(19) United States
(12) Patent Application Publication
(10) Pub. No.: US 2019/0169020 A1
(43) Pub. Date: Jun. 6, 2019

(54) PACKAGE SUBSTRATE INTEGRATED DEVICES

(71) Applicant: Intel Corporation, Santa Clara, CA (US)

(72) Inventors: Aleksandar ALEKSOV, Chandler, AZ (US); Kristof DARMAWIKARTA, Chandler, AZ (US); Robert A. MAY, Chandler, AZ (US); Changhua LIU, Chandler, AZ (US); Hiroki TANAKA, Suzuki-Shi (JP); Feras EID, Chandler, AZ (US)

(73) Assignee: Intel Corporation, Santa Clara, CA (US)

(21) Appl. No.: 15/832,223

(22) Filed: Dec. 5, 2017

(51) Int. Cl. B81B 7/02; B81C 1/00; H01L 23/498

(52) U.S. Cl. CPC B81B 7/02; B81C 1/00634; H01L 23/49838; B81B 2203/0118; B81B 2207/012; H01L 24/16; B81C 2201/0108; B81C 2201/0109; B81C 2201/0157; B81C 2203/0136; B81C 2203/0109; B81B 2207/092

(57) ABSTRACT

A package substrate is provided which comprises: one or more first conductive contacts on a first surface; one or more second conductive contacts on a second surface opposite the first surface; a dielectric layer between the first and the second surfaces; and an embedded sensing or actuating element on the dielectric layer conductively coupled with one of the first conductive contacts, wherein the embedded sensing or actuating element comprises a fixed metal layer in the dielectric layer and a flexible metal layer suspended over the fixed metal layer by one or more metal supports on the dielectric layer. Other embodiments are also disclosed and claimed.

### BACKGROUND

Computing platforms, such as smart phones or tablets, for example, may include multiple sensors and/or actuators to provide advanced features. In many cases, micro electrical mechanical systems (MEMS) are used to implement these advanced features such as user interface or user experience features, for example. Examples of sensors may include accelerometers, gyroscopes, and pressure sensors. Examples of actuators may include haptic actuators, radio frequency (RF) switches, and micropumps. Conventionally these MEMS sensors and actuators are manufactured using silicon technology and subsequently packaged and assembled as one or more discrete components on a motherboard or integrated circuit package, for example. This approach requires expensive silicon based manufacturing, adds significant z-height to the package or board, and requires assembly of the discrete components.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates an example circuit that may be implemented with package substrate integrated devices, according to some embodiments,

FIGS. 2A-2H illustrate cross-sectional views of manufacturing steps of a package substrate integrated device, according to some embodiments,

FIGS. 3A-3J illustrate views of manufacturing steps of a package substrate integrated device, according to some embodiments,

FIG. 4 illustrates a cross-sectional view of an example system with package substrate integrated devices, according to some embodiments,

FIG. 5 illustrates a flowchart of a method of forming package substrate integrated devices, in accordance with some embodiments, and

FIG. 6 illustrates a smart device or a computer system or a SoC (System-on-Chip) which includes package substrate integrated devices, according to some embodiments.

### DETAILED DESCRIPTION

Package substrate integrated devices are generally presented. In this regard, embodiments of the present disclosure enable sensing or actuating elements to be formed as part of a package substrate. One skilled in the art would appreciate that these sensing or actuating elements may be formed using existing substrate manufacturing techniques and, in some embodiments, without the need for unique tools. In one embodiment, the disclosed sensing or actuating elements can be formed without reactive ion etching (RIE) tools. Additionally, in some embodiments, the sensing or actuating elements described herein may include finer pitch features compared to discrete components and thereby enable integration of more components and enhanced features.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

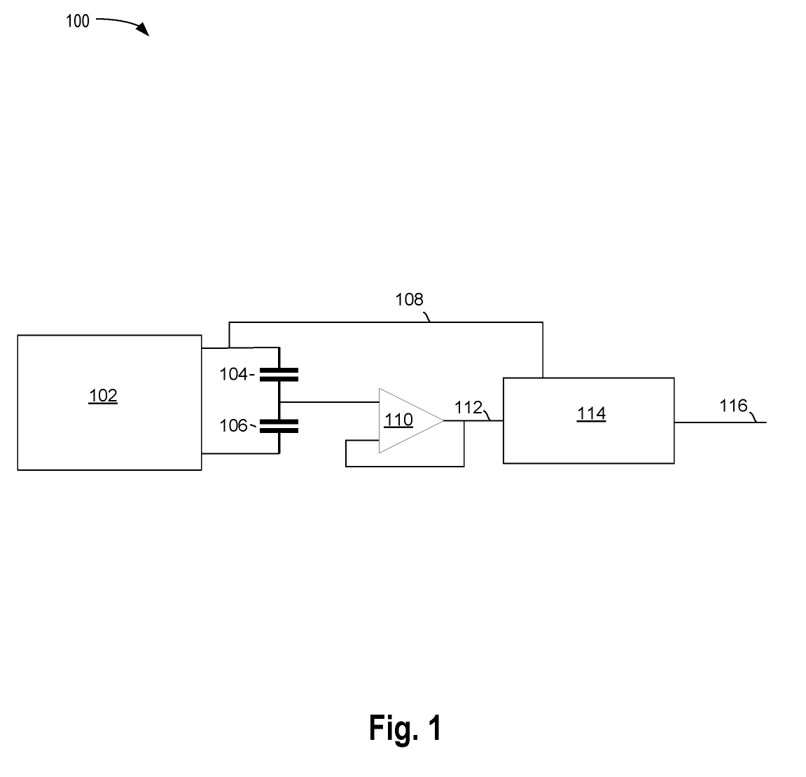

FIG. 1 illustrates an example circuit that may be implemented with package substrate integrated devices, according to some embodiments. As shown, MEMS circuit 100 includes oscillator 102, sensing or actuating elements 104 and 106, original signal 108, buffer 110, modified signal 112, demodulator 114, and output 116. In some embodiments, MEMS circuit 100 may represent an accelerometer, in which elements 104 and 106 are sensing capacitors, however in other embodiments, MEMS circuit 100 may represent, or be modified to represent, other sensor or actuator functions.

In some embodiments, oscillator 102 may generate an oscillating voltage. In some embodiments, original signal 108 may represent a 1 MHz square wave, however any wave form and frequency may be used. In some embodiments, oscillator 102 may provide a voltage to sensing capacitor 106 inverse to original signal 108 provided to sensing capacitor 104. The voltage between sensing or actuating elements 104 and 106 may then be provided to buffer 110, which stores any value.

Sensing or actuating elements 104 and 106 may be implemented as part of a package substrate, as described in more detail hereinafter, and may include at least one flexible plate that is able to deflect upon acceleration in a particular direction, and temporarily vary in capacitance. In some embodiments, sensing or actuating elements 104 and 106 may be oriented in opposite directions of an axis such that an inward deflection (and decrease in capacitance) in sensing capacitor 104 would result in an outward deflection (and increase in capacitance) in sensing capacitor 106, for example. In some embodiments, sensing or actuating elements 104 and 106 may be implemented in circuits of greater or lesser complexity than MEMS circuit 100.

Demodulator 114 may compare original signal 108 with modified signal 112. In some embodiments, demodulator 114 may generate output 116 based on a delta between original signal 108 and modified signal 112, representing a magnitude of acceleration, for example. In some embodiments, output 116 is routed to a processor or controller, for example, as a user input to an interface or operating system.

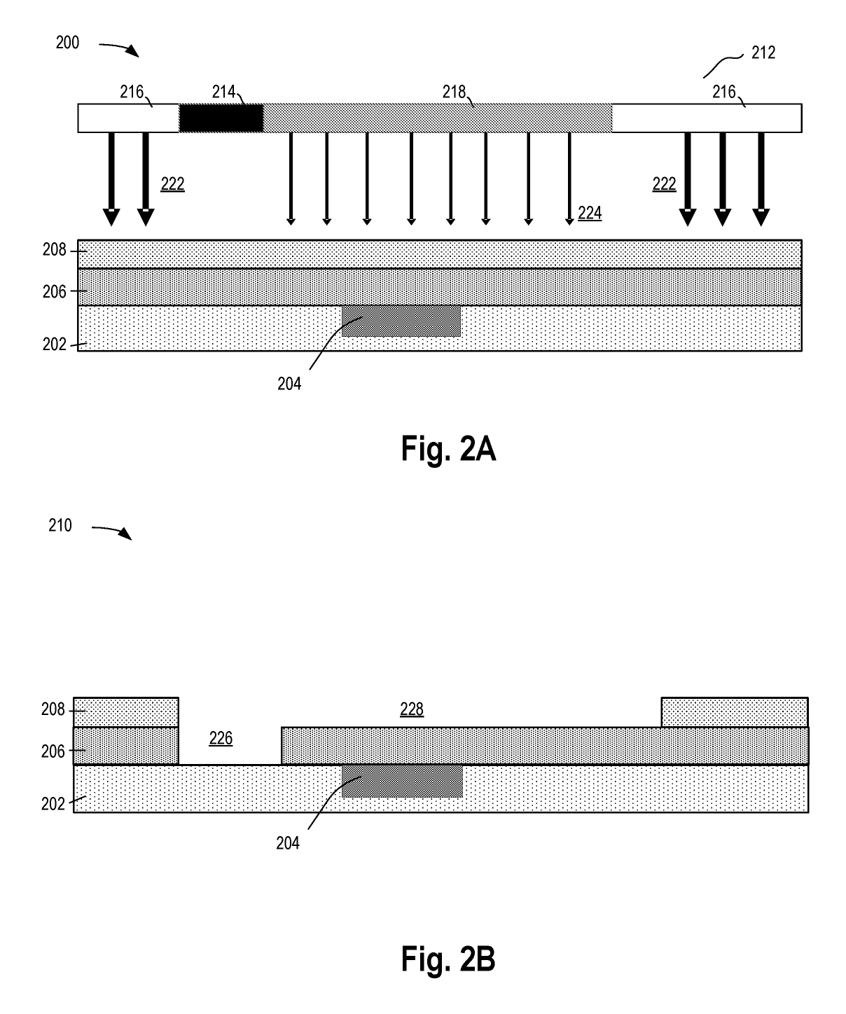

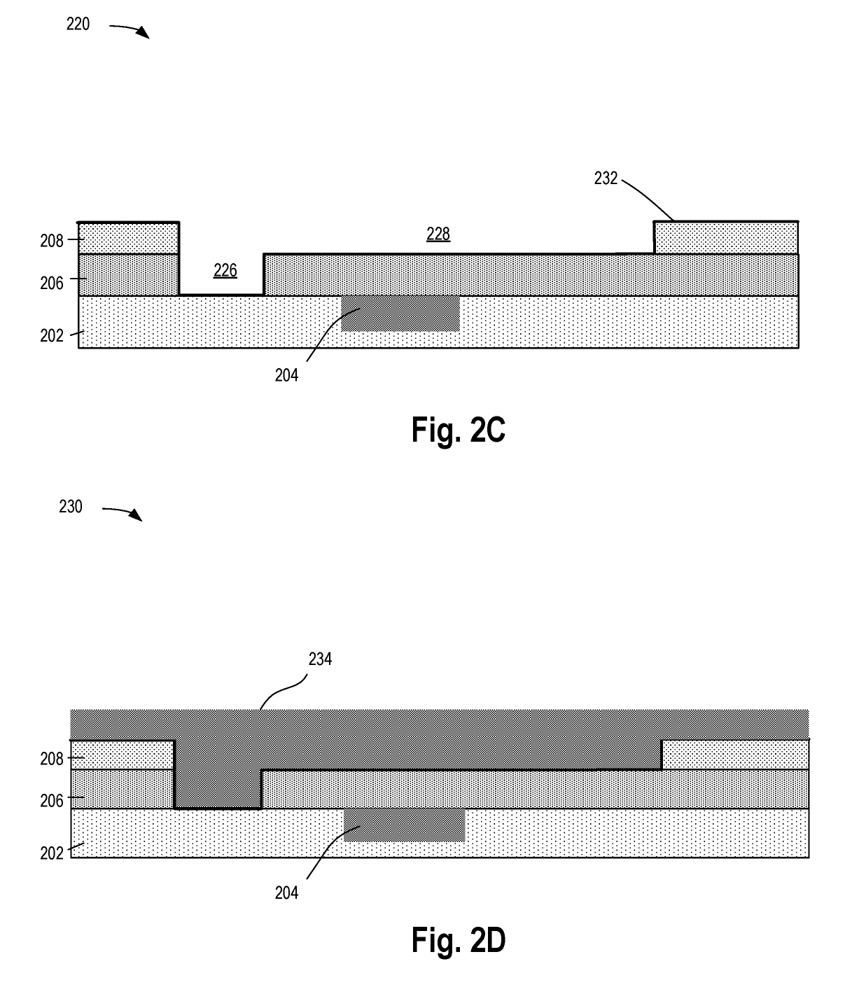

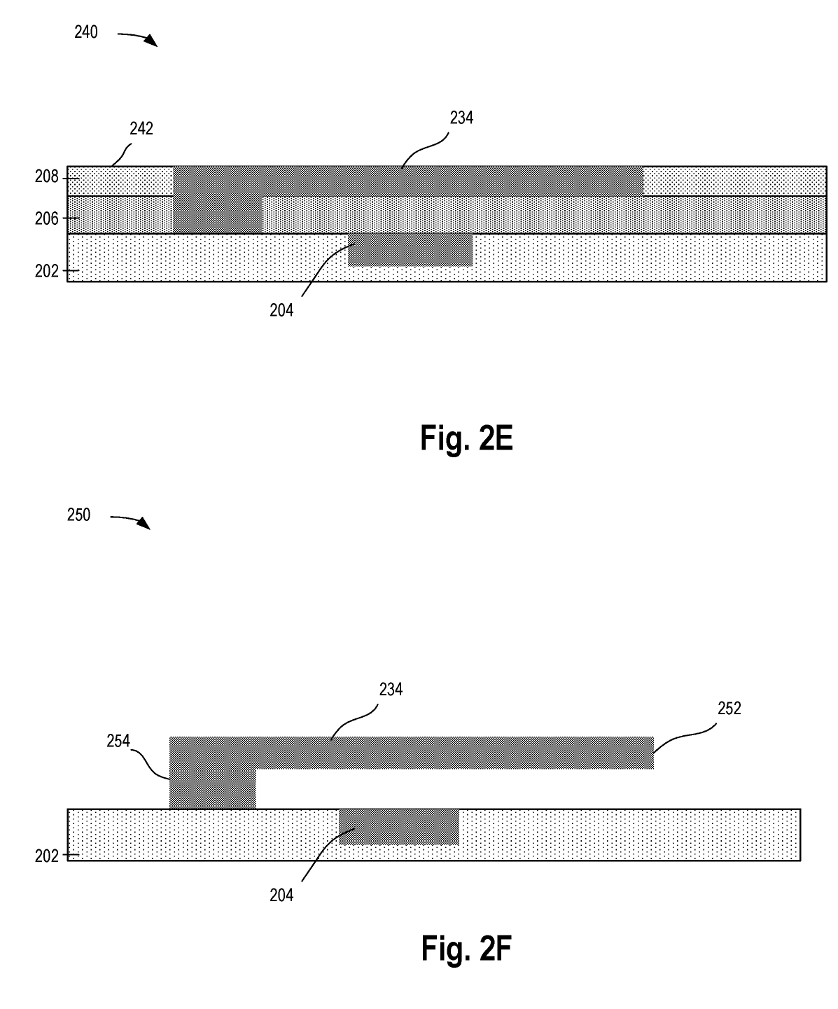

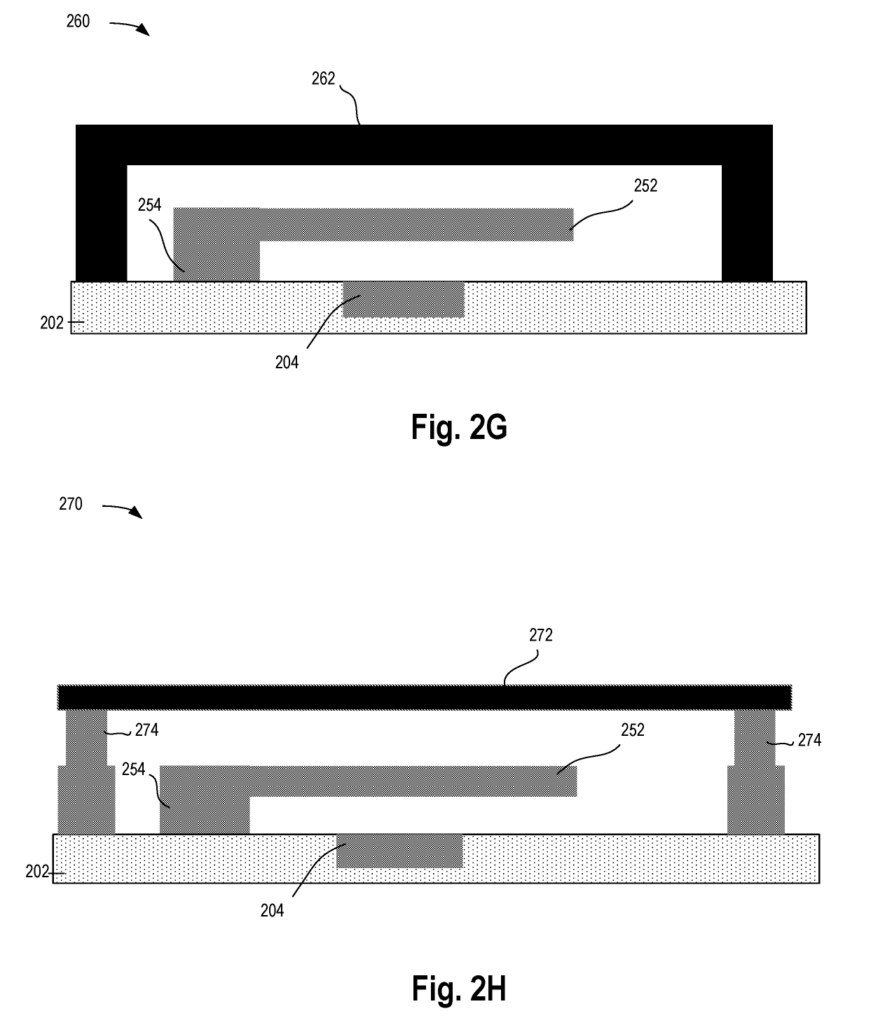

FIGS. 2A-2H illustrate cross-sectional views of manufacturing steps of a package substrate integrated device, according to some embodiments. As shown in FIG. 2A, assembly 200 includes substrate 202, fixed metal layer 204, photoresist materials 206 and 208, mask 212, opaque region 214, transparent regions 216, semi-transparent region 218, and light levels 222 and 224. In some embodiments, substrate 202 represents a dielectric buildup film, such as an epoxy dielectric or a polymer, for example, that contains fixed metal layer 204, which may be copper, for example. Also, assembly 200 may include additional layers not shown.

Photoresist materials 206 and 208 may be wet photoresist or dry film resist (DFR), for example. In this example embodiment, photoresist materials 206 and 208 are negative-tone photoresists in which the portion of the photoresist that is exposed to light becomes insoluble to the photoresist developer, however in other embodiments, positive photoresists may be used. While shown as having substantially similar thicknesses, photoresist materials 206 and 208 may have different thicknesses.

In some embodiments, photoresist materials 206 and 208 differ in photosensitivity, such that while a higher light level, such as light level 222, provided through transparent regions 216 of mask 212 would alter the solubility of both photoresist materials 206 and 208, a lower light level, such as light level 224, provided through semi-transparent region 218 would only alter the solubility of photoresist material 206 to a particular developer and not photoresist material 208, for example. In some embodiments, regions of photoresist materials 206 and 208 that are not exposed to light, for example those regions blocked by opaque region 214 would not experience solubility changes.

FIG. 2B shows assembly 210, which may include opening 228 developed in photoresist material 208 and opening 226 developed through both photoresist materials 206 and 208. In some embodiments, a single developer may be used to form openings 226 and 228, while in other embodiments, multiple developers may be used separately or together.

As shown in FIG. 2C, assembly 220 may have had seed layer 232 deposited on exposed surfaces of substrate 202 and photoresist materials 206 and 208. In some embodiments, seed layer 232 may represent copper or titanium copper alloy or some other alloy that may be deposited by electroless plating or sputter deposition.

Turning now to FIG. 2D, assembly 230 may include metal plating 234 over seed layer 232. In some embodiments, copper may be deposited by electro or electroless plating in one layer or in multiple stacked layers.

FIG. 2E shows assembly 240, which may have had excess metal plating 234 removed down to photoresist material surface 242. In some embodiments, excess metal plating 234 may be removed by grinding, polishing, and/or chemical mechanical planarization (CMP).

As shown in FIG. 2F, for assembly 250 photoresist materials 206 and 208 have been removed exposing metal plating 234, including suspended metal layer 252 and metal support 254. While shown as being cantilevered from a single metal support 254, in some embodiments, suspended metal layer 252 may be supported by more than one metal support 254. In some embodiments, photoresist materials 206 and 208 are removed with a single chemical remover, while in other embodiments, separate chemical removers may be used to remove photoresist layers 206 and 208.

In some embodiments, suspended metal layer 252 may remain a constant distant from fixed metal layer 204 when no force is applied to the structure, and suspended metal layer 252 may, due to inertia, deflect closer to, or further away from, fixed metal layer 204 when a force is applied to the structure. In some embodiments, the deflection of suspended metal layer 252 into adjacent space results in a temporary change in capacitance between suspended metal layer 252 and fixed metal layer 204.

Turning now to FIG. 2G, assembly 260 may include housing 262 on substrate 202 surrounding suspended metal layer 252. In some embodiments, housing 262 provides environmental protection to suspended metal layer 252 and may include any suitable material including, but not limited to, plastic or metal. In some embodiments, housing 262 is adhered to substrate 202 with adhesive, such as an adhesive paste.

FIG. 2H shows assembly 270, which may include lid 272 attached to metal columns 274 as an alternative to housing 262. In some embodiments, metal columns 274 were at least partially formed by plating additional openings in the previously removed photoresist materials. In some embodiments, lid 272, which may be metal or plastic, for example, is adhered to metal columns 274 with adhesive paste.

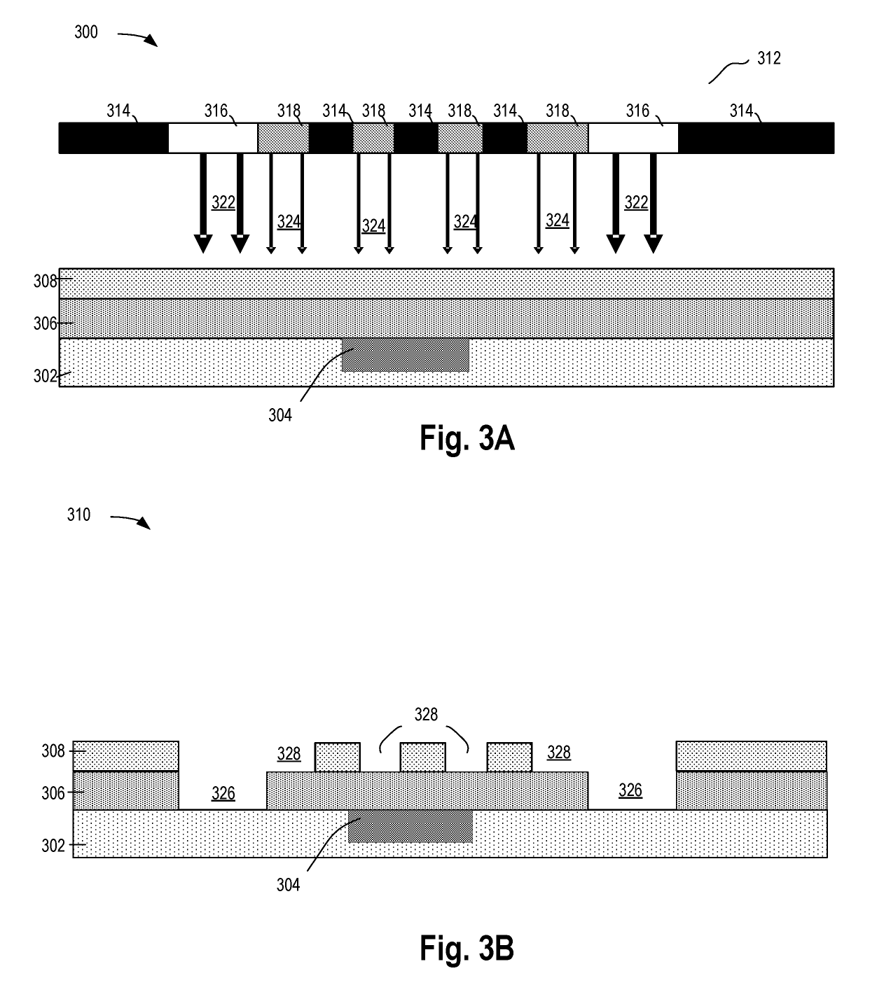

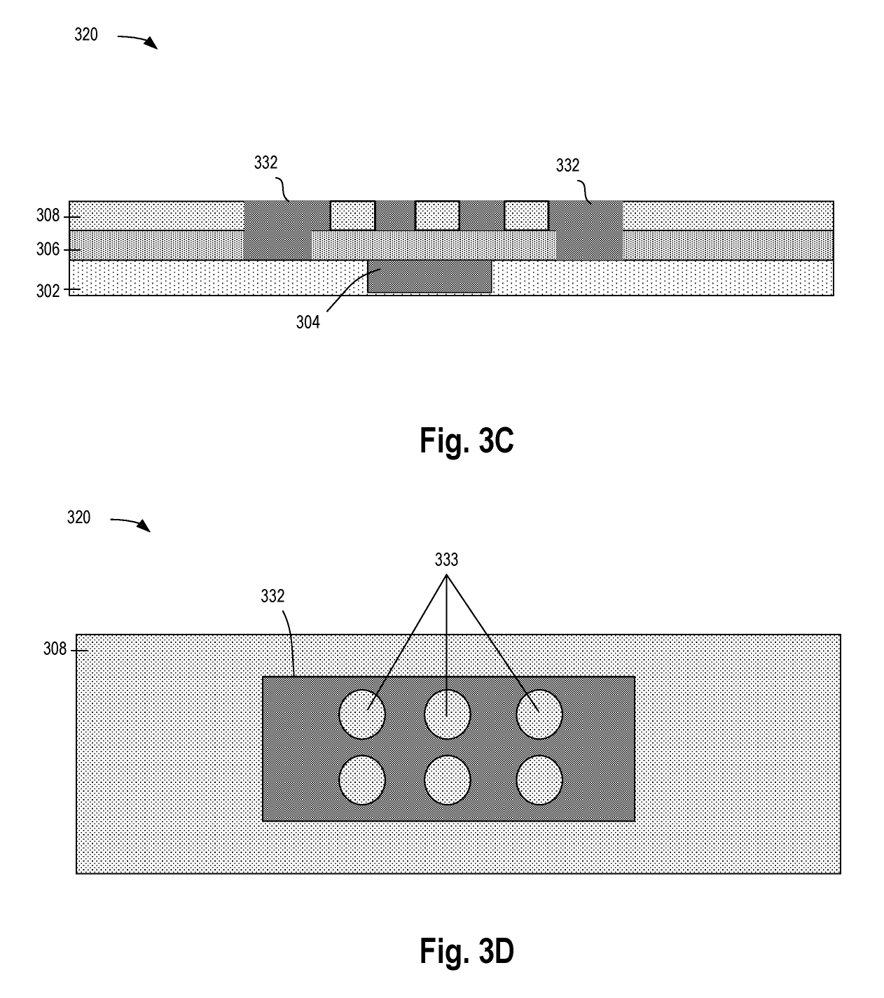

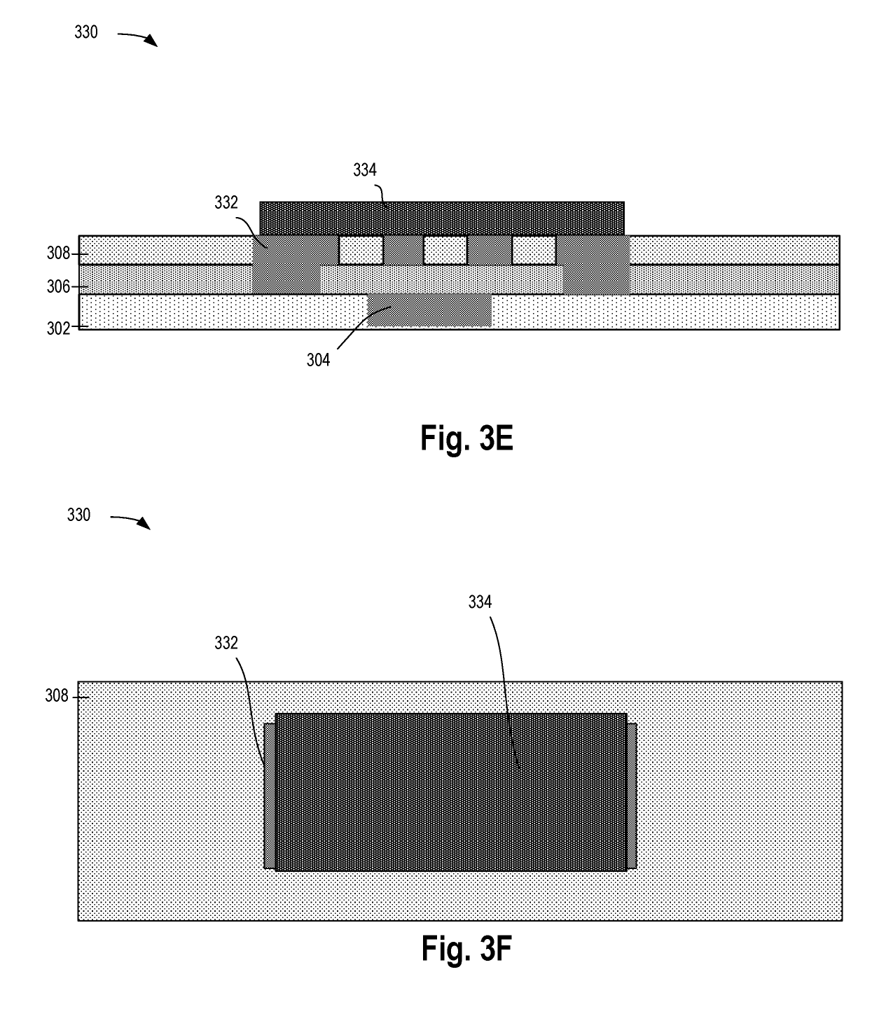

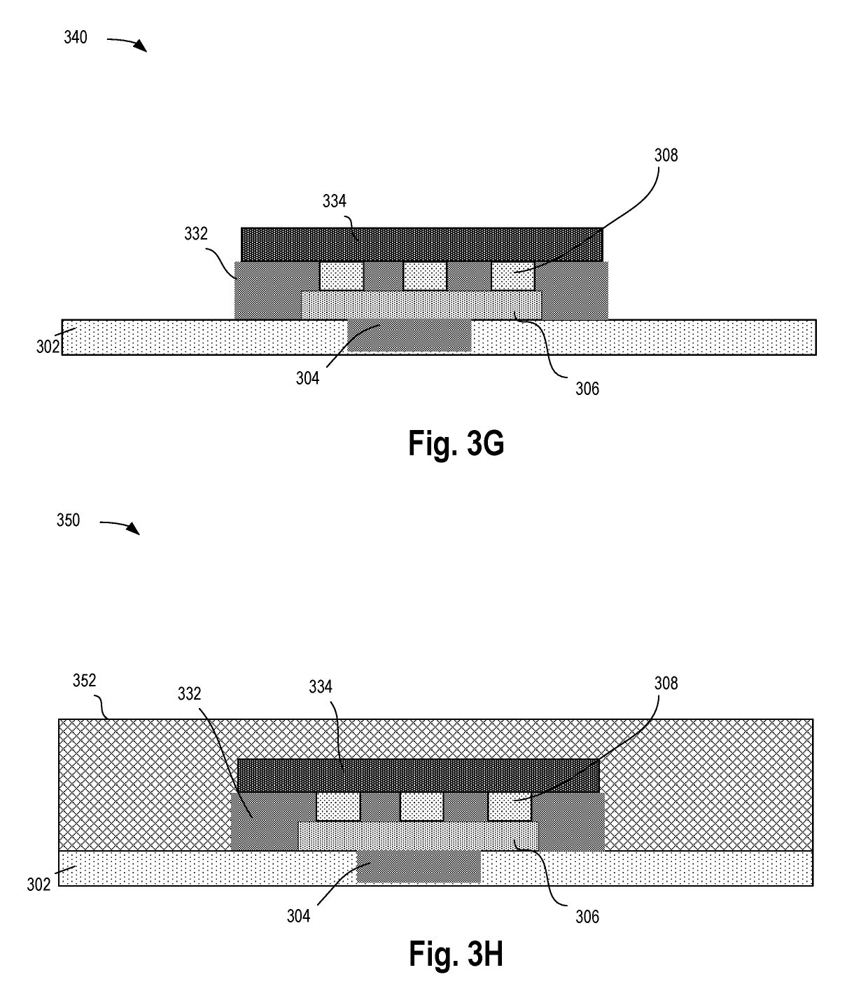

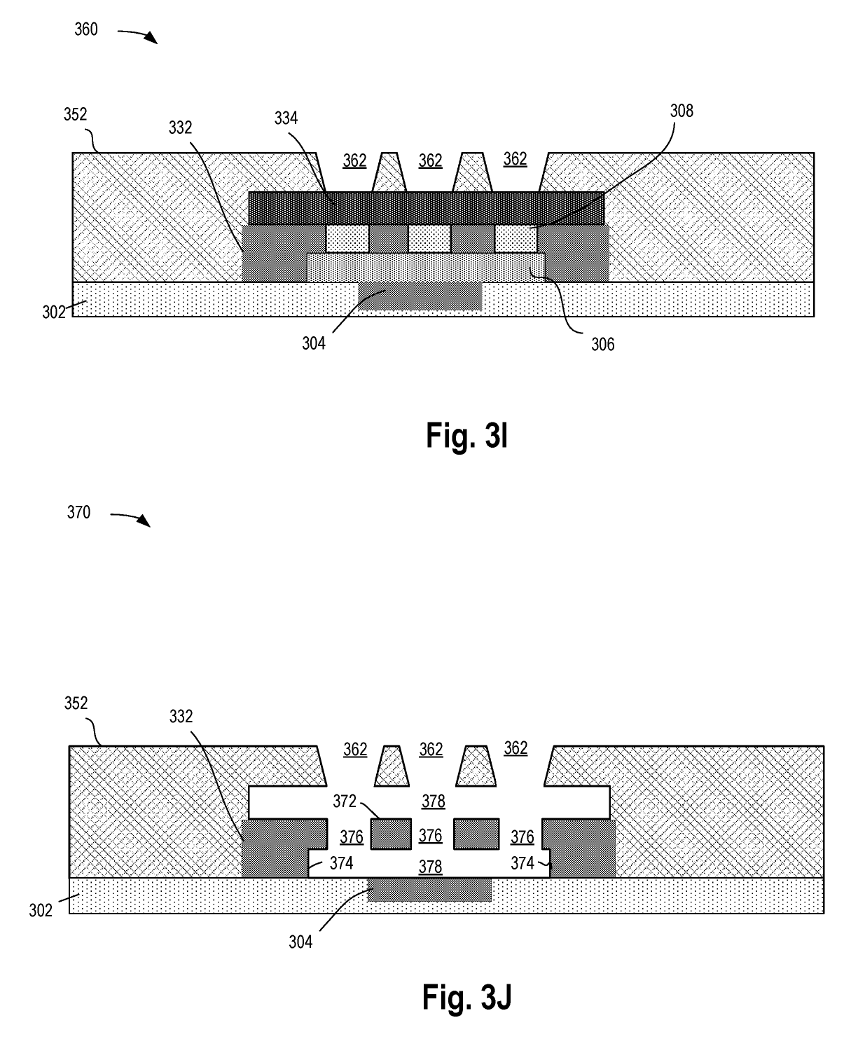

FIGS. 3A-3J illustrate views of manufacturing steps of a package substrate integrated device, according to some embodiments. As shown in FIG. 3A, assembly 300 includes substrate 302, fixed metal layer 304, photoresist materials 306 and 308, mask 312, opaque regions 314, transparent regions 316, semi-transparent regions 318, and light levels 322 and 324. In some embodiments, substrate 302 represents a dielectric buildup film, such as an epoxy dielectric or a polymer, for example, that contains fixed metal layer 304, which may be copper, for example. Also, assembly 300 may include additional layers not shown.

Photoresist materials 306 and 308 may be wet photoresist or dry film resist (DFR), for example. In this example embodiment, photoresist materials 306 and 308 are positive-tone photoresists in which the portion of the photoresist that is exposed to light becomes soluble to the photoresist developer, however in other embodiments, negative photoresists may be used. While shown as having substantially similar thicknesses, photoresist materials 306 and 308 may have different thicknesses.

In some embodiments, photoresist materials 306 and 308 differ in photosensitivity, such that while a higher light level, such as light level 322, provided through transparent regions 316 of mask 312 would alter the solubility of both photoresist materials 306 and 308, a lower light level, such as light level 324, provided through semi-transparent region 318 would only alter the solubility of photoresist material 308 to a particular developer and not photoresist material 306, for example. In some embodiments, regions of photoresist materials 306 and 308 that are not exposed to light, for example those regions blocked by opaque regions 314 would not experience solubility changes.

FIG. 3B shows assembly 310, which may include openings 328 developed in photoresist material 308 and openings 326 developed through both photoresist materials 306 and 308. In some embodiments, a single developer may be used to form openings 326 and 328, while in other embodiments, multiple developers may be used separately or together.

As shown in FIG. 3C, assembly 320 may have had openings 326 and 328 filled with metal plating 332. In some embodiments, metal plating 332 has been planarized with a surface of photoresist material 308.

FIG. 3D illustrates a plan view of assembly 320. As shown, metal plating 332 may be rectangular in shape, however other regular or irregular shapes may be used. Openings 333 may be present in metal plating 332 as a result of patterning of photoresist material 308. In some embodiments, openings 333 may round and arranged linearly, however other shapes and arrangements, may be used. In some embodiments, openings 333 may enable efficient removal of photoresist material (306) under metal plating 332 in subsequent processing.

Turning now to FIG. 3E, assembly 330 may include sacrificial material 334 formed over metal plating 332. In some embodiments, sacrificial material 334 is a photoresist material, or other material, that is able to withstand the chemical removal of photoresist materials 306 and 308.

FIG. 3F illustrates a plan view of assembly 330. As shown, sacrificial material 334 may cover openings 333 to prevent portions of photoresist material 306 and 308 from being exposed to chemical remover. In some embodiments, sacrificial material 334 may overhang one or more sides of metal plating 332.

FIG. 3G shows assembly 340, which may have had photoresist materials 306 and 308 removed from substrate 302 except for those portions of photoresist materials 306 and 308 under sacrificial material 334. In some embodiments, portions of photoresist materials 306 and 308 are removed by oxygen plasma ashing. In other embodiments, portions of photoresist materials 306 and 308 are removed by selective chemical removers.

As shown in FIG. 3H, for assembly 350 dielectric 352 is laminated on substrate 302. In some embodiments, dielectric 352 may include solder resist material or another polymer or other dielectric. While shown as extending well above sacrificial material 334, in some embodiments, dielectric 352 may extend only slightly above, or may be flush with, sacrificial material 334.

Turning now to FIG. 3I, assembly 360 may include openings 362 formed in dielectric 352 to expose sacrificial material 334. In some embodiments, openings 362 may be formed by laser ablation, or other mechanical or chemical means.

FIG. 3J shows assembly 370, which may have had sacrificial material 334 and photoresist materials 306 and 308 removed. In some embodiments, chemical remover may have been applied through openings 362 to remove sacrificial material 334 and photoresist materials 306 and 308. Metal plating 332 may include suspended metal layer 372, which may be adjacent voids 378 that allow for deflection of suspended metal layer 372, for example when a force is applied to the structure. While shown as including two metal supports 374 on opposite ends of suspended metal layer 372, in some embodiments suspended metal layer 372 may be cantilevered from a single metal support 374. In some embodiments, openings 376, which may include a series of round openings, are present in suspended metal layer 372 as necessary to enable the removal of the previously present photoresist materials.

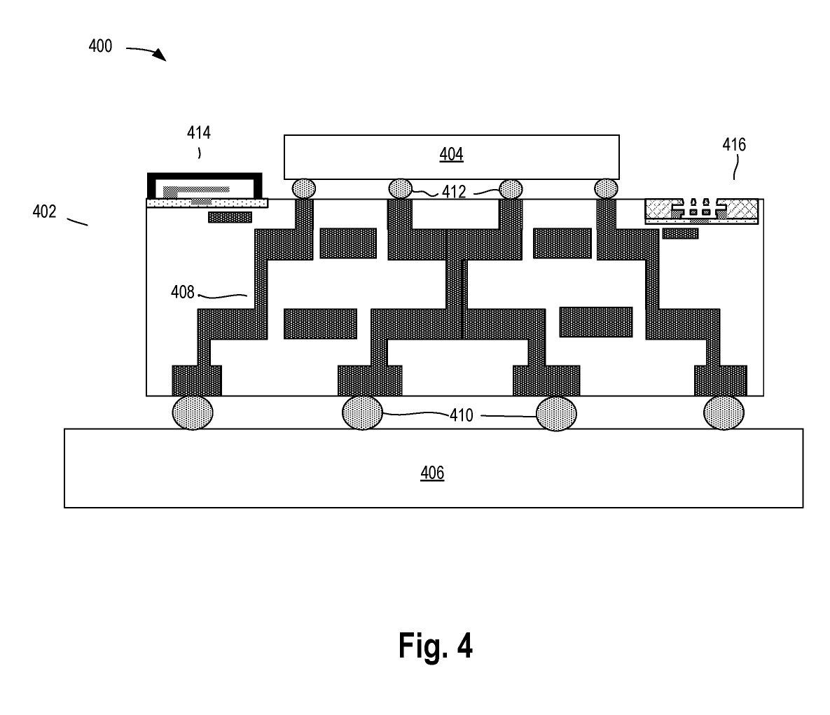

FIG. 4 illustrates a cross-sectional view of an example system with package substrate integrated devices, according to some embodiments. As shown, system 400 includes package substrate 402, integrated circuit device 404, system board 406, interconnect routing 408, solder balls 410, metal contacts 412, and sensing or actuating elements 414 and 416. Integrated circuit device 404 may represent any type of device, including, but not limited to a processor, a controller, an SOC, or a transceiver. Integrated circuit device 404 may include lands (not shown) to contact with metal contacts 412.

Interconnect routing 408 may be build-up layers of metal and dielectric that couple metal contacts 412 to solder balls 410. Interconnect routing 408 conductively couples sensing or actuating elements 414 and 416 with metal contacts 412 and/or solder balls 410. Package substrate 402 may include any number of sensing or actuating elements 414 (on a surface of package substrate 402, such as assembly 260) and/or sensing or actuating elements 416 (below a surface of package substrate 402, such as assembly 370) aligned along multiple axis. System board 406 may include other system components and may have solder pads (not shown) to couple with solder balls 410 of package substrate 402.

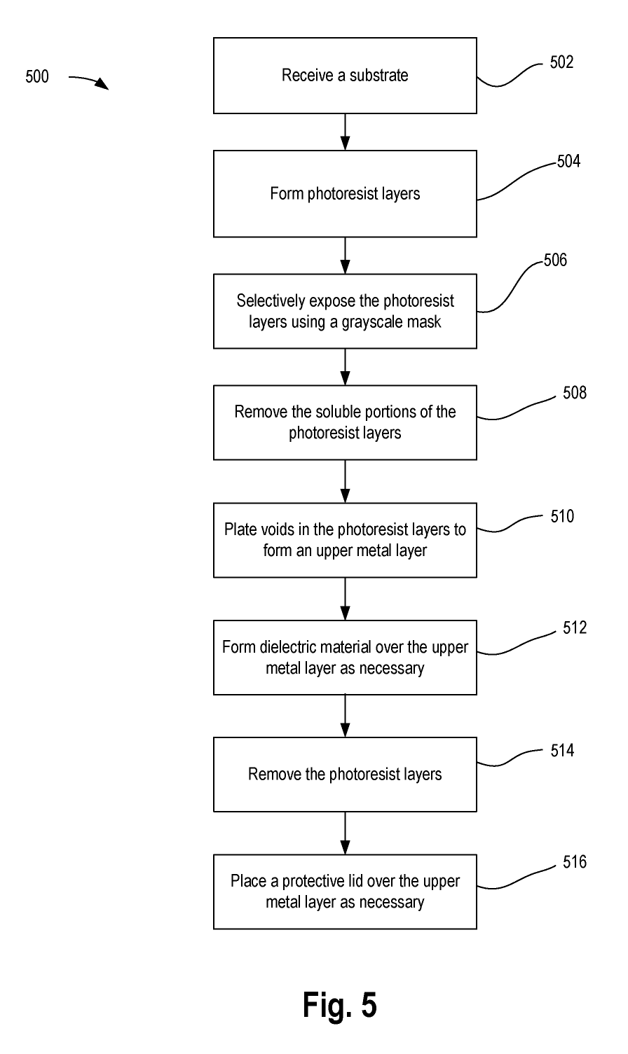

FIG. 5 illustrates a flowchart of a method of forming package substrate integrated devices, in accordance with some embodiments. Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 500 begins with receiving (502) a substrate. In some embodiments, a substrate, such as 202 may include fixed copper layers, such as 204. Next, photoresist layers are formed (504) on the substrate. In some embodiments, multiple photoresist materials, such as 206 and 208, having different photosensitivities are formed on substrate 202.

Then, the photoresist layers are selectively exposed (506) to light using a grayscale mask. In some embodiments, a grayscale mask, such as mask 212, includes opaque, transparent, and semi-transparent regions to allow different light levels to reach the photoresist materials. Next, one or more developer(s) may be applied to remove (508) the soluble portions of the photoresist layers.

The method continues with plating (510) voids in the photoresist layers to form an upper metal layer. In some embodiments, a seed layer, such as seed layer 232 is first deposited before metal plating 234 is overplated and then planarized. Next, in some embodiments, dielectric material may be formed (512) over the upper metal layer as necessary. In some embodiments, sacrificial material, such as sacrificial material 334 is formed over the upper metal layer before dielectric 352 is deposited.

Next, the photoresist layers may be removed (514) for example using one or more chemical removers. Finally, in some embodiments, a protective lid may be placed (516), such as housing 262 for example, over the upper metal layer for protection.

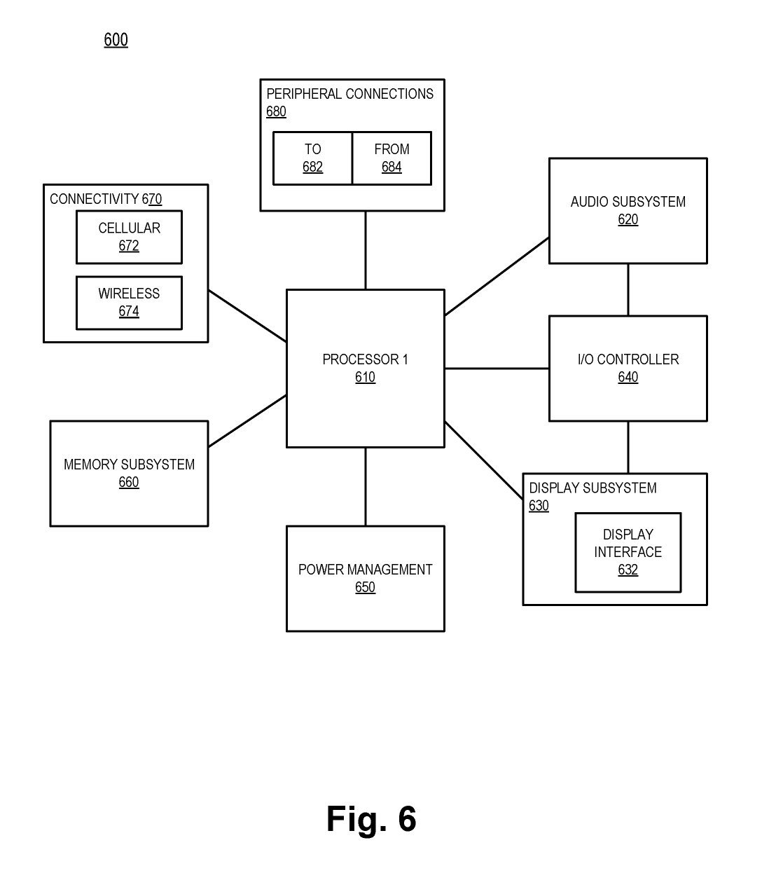

FIG. 6 illustrates a smart device or a computer system or a SoC (System-on-Chip) which includes package substrate integrated devices, according to some embodiments. In some embodiments, computing device 600 represents a mobile computing device, such as a computing tablet, a mobile phone or smart-phone, a wireless-enabled e-reader, or other wireless mobile device. It will be understood that certain components are shown generally, and not all components of such a device are shown in computing device 600. In some embodiments, one or more components of computing device 600, for example processor 610 or I/O controller 640, include a package substrate with integrated devices as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 600 includes a first processor 610. The various embodiments of the present disclosure may also comprise a network interface within 670 such as a wireless interface so that a system embodiment may be incorporated into a wireless device, for example, cell phone or personal digital assistant.

In one embodiment, processor 610 can include one or more physical devices, such as microprocessors, application processors, microcontrollers, programmable logic devices, or other processing means. The processing operations performed by processor 610 include the execution of an operating platform or operating system on which applications and/or device functions are executed. The processing operations include operations related to I/O (input/output) with a human user or with other devices, operations related to power management, and/or operations related to connecting the computing device 600 to another device. The processing operations may also include operations related to audio I/O and/or display I/O.

In one embodiment, computing device 600 includes audio subsystem 620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 600, or connected to the computing device 600. In one embodiment, a user interacts with the computing device 600 by providing audio commands that are received and processed by processor 610.

Display subsystem 630 represents hardware (e.g., display devices) and software (e.g., drivers) components that provide a visual and/or tactile display for a user to interact with the computing device 600. Display subsystem 630 includes display interface 632, which includes the particular screen or hardware device used to provide a display to a user. In one embodiment, display interface 632 includes logic separate from processor 610 to perform at least some processing related to the display. In one embodiment, display subsystem 630 includes a touch screen (or touch pad) device that provides both output and input to a user.

I/O controller 640 represents hardware devices and software components related to interaction with a user. I/O controller 640 is operable to manage hardware that is part of audio subsystem 620 and/or display subsystem 630. Additionally, I/O controller 640 illustrates a connection point for additional devices that connect to computing device 600 through which a user might interact with the system. For example, devices that can be attached to the computing device 600 might include microphone devices, speaker or stereo systems, video systems or other display devices, keyboard or keypad devices, or other I/O devices for use with specific applications such as card readers or other devices.

As mentioned above, I/O controller 640 can interact with audio subsystem 620 and/or display subsystem 630. For example, input through a microphone or other audio device can provide input or commands for one or more applications or functions of the computing device 600. Additionally, audio output can be provided instead of, or in addition to display output. In another example, if display subsystem 630 includes a touch screen, the display device also acts as an input device, which can be at least partially managed by I/O controller 640. There can also be additional buttons or switches on the computing device 600 to provide I/O functions managed by I/O controller 640.

In one embodiment, I/O controller 640 manages devices such as accelerometers, cameras, light sensors or other environmental sensors, or other hardware that can be included in the computing device 600. The input can be part of direct user interaction, as well as providing environmental input to the system to influence its operations (such as filtering for noise, adjusting displays for brightness detection, applying a flash for a camera, or other features).

In one embodiment, computing device 600 includes power management 650 that manages battery power usage, charging of the battery, and features related to power saving operation. Memory subsystem 660 includes memory devices for storing information in computing device 600. Memory can include nonvolatile (state does not change if power to the memory device is interrupted) and/or volatile (state is indeterminate if power to the memory device is interrupted) memory devices. Memory subsystem 660 can store application data, user data, music, photos, documents, or other data, as well as system data (whether long-term or temporary) related to the execution of the applications and functions of the computing device 600.

Elements of embodiments are also provided as a machine-readable medium (e.g., memory 660) for storing the computer-executable instructions. The machine-readable medium (e.g., memory 660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 670 includes hardware devices (e.g., wireless and/or wired connectors and communication hardware) and software components (e.g., drivers, protocol stacks) to enable the computing device 600 to communicate with external devices. The computing device 600 could be separate devices, such as other computing devices, wireless access points or base stations, as well as peripherals such as headsets, printers, or other devices.

Connectivity 670 can include multiple different types of connectivity. To generalize, the computing device 600 is illustrated with cellular connectivity 672 and wireless connectivity 674. Cellular connectivity 672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 680 include hardware interfaces and connectors, as well as software components (e.g., drivers, protocol stacks) to make peripheral connections. It will be understood that the computing device 600 could both be a peripheral device (“to” 682) to other computing devices, as well as have peripheral devices (“from” 684) connected to it. The computing device 600 commonly has a “docking” connector to connect to other computing devices for purposes such as managing (e.g., downloading and/or uploading, changing, synchronizing) content on computing device 600. Additionally, a docking connector can allow computing device 600 to connect to certain peripherals that allow the computing device 600 to control content output, for example, to audiovisual or other systems.

In addition to a proprietary docking connector or other proprietary connection hardware, the computing device 600 can make peripheral connections 680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

In one example, a package substrate is provided comprising: one or more first conductive contacts on a first surface; one or more second conductive contacts on a second surface opposite the first surface; a dielectric layer between the first and the second surfaces; and an embedded sensing or actuating element on the dielectric layer conductively coupled with one of the first conductive contacts, wherein the embedded sensing or actuating element comprises a first metal layer in the dielectric layer and a second metal layer suspended over the first metal layer by one or more metal supports on the dielectric layer.

Some embodiments also include a protective housing over the embedded sensing or actuating element, the protective housing extending beyond the first surface. In some embodiments, the protective housing comprises copper supports extending from the first surface. Some embodiments also include a second dielectric layer over the embedded sensing or actuating element. In some embodiments, the second dielectric layer comprises one or more openings adjacent the embedded sensing or actuating element. In some embodiments, the second metal layer comprises one or more round openings. In some embodiments, the second metal layer is cantilevered over the first metal layer. In some embodiments, the second metal layer is supported on opposite ends by metal supports.

In another example, a system is provided comprising: a processor; a communication interface; and an integrated circuit device package, the integrated circuit device package comprising: an integrated circuit device coupled with one or more first conductive contacts on a first substrate surface; one or more second conductive contacts on a second substrate surface opposite the first substrate surface; a dielectric layer between the first and the second substrate surfaces; and an embedded capacitor on the dielectric layer conductively coupled with the integrated circuit device, wherein the embedded capacitor comprises a fixed metal layer in the dielectric layer and a flexible metal layer suspended over the fixed metal layer by one or more metal supports on the dielectric layer.

In some embodiments, the embedded capacitor comprises a protective housing that extends beyond the first substrate surface. In some embodiments, the protective housing comprises copper supports extending from the first substrate surface. Some embodiments also include a second dielectric layer over the embedded capacitor. In some embodiments, the second dielectric layer comprises one or more openings adjacent the embedded capacitor. In some embodiments, the flexible metal layer comprises one or more openings. In some embodiments, the flexible metal layer is cantilevered over the fixed metal layer. In some embodiments, the flexible metal layer is supported on opposite ends by metal supports.

In another example, a method of manufacturing a package substrate is provided comprising: forming a first photoresist material over an embedded metal layer on a substrate surface; forming a second photoresist material over the first photoresist material, wherein the second photoresist material comprises a different photosensitivity than the first photoresist material; selectively exposing portions of the first and second photoresist materials to a first light level and a second light level, wherein the first light level changes solubility of both the first and second photoresist materials and the second light level changes solubility of the second photoresist material and doesn't change the solubility of the first photoresist material; applying developer to remove the soluble portions of the first and second photoresist materials; plating voids in the first and second photoresist layers to form an upper metal layer parallel to the embedded metal layer; and removing the first and second photoresist materials.

Some embodiments also include forming openings in the upper metal layer. In some embodiments, the first and second photoresist materials comprise negative photoresist materials. Some embodiments also include forming a protective lid over the upper metal layer. In some embodiments, forming the protective lid comprises forming metal columns on the substrate surface. Some embodiments also include forming a third photoresist material over the upper metal layer. Some embodiments also include forming a dielectric layer surrounding the third photoresist material and upper metal layer. Some embodiments also include forming openings in the dielectric layer to expose the third photoresist material.

In another example, a system is provided comprising: a display subsystem; a wireless communication interface; and a microelectromechanical systems (MEMS) circuit, the MEMS circuit comprising: an oscillator to generate an oscillating voltage; and an embedded sensing capacitor on a dielectric layer of a package substrate conductively coupled with the oscillator, wherein the embedded sensing capacitor comprises a first metal layer in the dielectric layer and a second metal layer suspended over the first metal layer by one or more metal supports on the dielectric layer.

In some embodiments, the second metal layer is adjacent a void into which the second metal layer is able to deflect. In some embodiments, the MEMS circuit comprises an accelerometer. In some embodiments, the second metal layer comprises one or more round openings. Some embodiments also include a protective housing over the embedded sensing capacitor, the protective housing extending beyond the dielectric layer. In some embodiments, the second metal layer is cantilevered over the first metal layer.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. A package substrate comprising:
one or more first conductive contacts on a first surface;
one or more second conductive contacts on a second surface opposite the first surface;
a dielectric layer between the first and the second surfaces; and
an embedded sensing or actuating element on the dielectric layer conductively coupled with one of the first conductive contacts, wherein the embedded sensing or actuating element comprises a first metal layer in the dielectric layer and a second metal layer suspended over the first metal layer by one or more metal supports on the dielectric layer^{.} and
an elevated sensing or actuating element on the first surface conductively coupled with one of the first conductive contacts, wherein the elevated sensing or actuating element comprises a third metal layer in the first surface and a fourth metal layer suspended over the third metal layer by one or more metal supports on the first surface.

2. The package substrate of claim 1, further comprising a protective housing over the embedded sensing or actuating element, the protective housing extending beyond the first surface.

3. The package substrate of claim 2, wherein the protective housing comprises copper supports extending from the first surface.

4. The package substrate of claim 1, further comprising a second dielectric layer over the embedded sensing or actuating element.

5. The package substrate of claim 4, wherein the second dielectric layer comprises one or more openings adjacent the embedded sensing or actuating element.

6. The package substrate of claim 1, wherein the second metal layer comprises one or more round openings.

7. The package substrate of claim 1, wherein the second metal layer is cantilevered over the first metal layer.

8. The package substrate of claim 1, wherein the second metal layer is supported on opposite ends by metal supports.

9. A system comprising:
a processor;
a communication interface; and
an integrated circuit device package, the integrated circuit device package comprising:
an integrated circuit device coupled with one or more first conductive contacts on a first substrate surface;
one or more second conductive contacts on a second substrate surface opposite the first substrate surface;
a dielectric layer between the first and the second substrate surfaces; and
an embedded capacitor on the dielectric layer conductively coupled with the integrated circuit device, wherein the embedded capacitor comprises a fixed metal layer in the dielectric layer and a flexible metal layer suspended over the fixed metal layer by one or more metal supports on the dielectric layer^{.} and
an elevated capacitor on the first substrate surface conductively coupled with the integrated circuit device, wherein the elevated capacitor comprises a fixed metal layer in the first substrate surface and a flexible metal layer suspended over the fixed metal layer by one or more metal supports on the first substrate surface.

10. The system of claim 9, wherein the embedded capacitor comprises a protective housing that extends beyond the first substrate surface.

11. The system of claim 10, wherein the protective housing comprises copper supports extending from the first substrate surface.

12. The system of claim 9, further comprising a second dielectric layer over the embedded capacitor.

13. The system of claim 12, wherein the second dielectric layer comprises one or more openings adjacent the embedded capacitor.

14. The system of claim 9, wherein the flexible metal layer comprises one or more openings.

15. The system of claim 9, wherein the flexible metal layer is cantilevered over the fixed metal layer.

16. The system of claim 9, wherein the flexible metal layer is supported on opposite ends by metal supports.

17. A method of manufacturing a package substrate comprising:
forming a first photoresist material over an embedded metal layer on a substrate surface;
forming a second photoresist material over the first photoresist material, wherein the second photoresist material comprises a different photosensitivity than the first photoresist material;
selectively exposing portions of the first and second photoresist materials to a first light level and a second light level, wherein the first light level changes solubility of both the first and second photoresist materials and the second light level changes solubility of the second photoresist material and doesn't change the solubility of the first photoresist material;
applying developer to remove the soluble portions of the first and second photoresist materials;
plating voids in the first and second photoresist layers to form an upper metal layer parallel to the embedded metal layer; and
removing the first and second photoresist materials.

18. The method of claim 17, further comprising forming openings in the upper metal layer.

19. The method of claim 17, wherein the first and second photoresist materials comprise negative photoresist materials.

20. The method of claim 17, further comprising forming a protective lid over the upper metal layer.

21. The method of claim 20, wherein forming the protective lid comprises forming metal columns on the substrate surface.

22. The method of claim 17, further comprising forming a third photoresist material over the upper metal layer.

23. The method of claim 22, further comprising forming a dielectric layer surrounding the third photoresist material and upper metal layer.

24. The method of claim 23, further comprising forming openings in the dielectric layer to expose the third photoresist material.
